(19) United States
(12) Patent Application Publication
(10) Pub. No.: US 2010/0133668 A1
(43) Pub. Date: Jun. 3, 2010

(54) Semiconductor device and manufacturing method thereof

(76) Inventor: Chung Hsing Tzu, ChungHe City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/591,275

(22) Filed: Nov. 16, 2009

Related U.S. Application Data
(60) Provisional application No. 61/119,048, filed on Dec. 2, 2008.

(51) Int. Cl. H01L 23/495; H01L 23/48; B32B 37/12; B32B 37/00; H01L 21/50

(52) U.S. Cl. 257/666; 257/783; 156/325; 156/73.1; 438/118; 257/E23.052; 257/E23.01; 257/E21.499

(57) ABSTRACT

The present invention relates to a semiconductor device, and more particularly to a manufacturing method for said semiconductor device. The semiconductor device comprises a die that connects with a substrate or a lead frame via an adhesion layer, a metal layer, and/or a back metal layer. Furthermore, the adhesion layer can be made of aluminum, and the die can connect with the substrate or the lead frame by ultrasonic bonding technology, which can avoid heat damaging the die during the manufacturing process.

### CROSS REFERENCE TO RELATED APPLICATIONS

This application claims priority of U.S. Provisional Application No. 61/119,048 filed on 2 Dec. 2008 under 35 U.S.C. §119(e), the entire contents of all of which are hereby incorporated by reference.

### FIELD OF THE INVENTION

The present invention relates to a semiconductor device, and more particularly to a manufacturing method for said semiconductor device.

### BACKGROUND

FIG. 1 is a diagrammatic illustration of a semiconductor device in accordance with a prior art. The typical semiconductor device 10 comprises a substrate 11 and a die 13. The die 13 comprises an active surface 131 and a back surface 133, and is positioned on the top surface of the substrate 11. Furthermore, a solder 15 is used to connect the die 13 and the substrate 11.

In the manufacturing process of semiconductor device 10, the solder 15 can be formed on the top surface of the substrate 11, and be heated to melt; for example, the solder 15 may melt at 300 degree centigrade. The die 13 can be positioned on the molten solder 15. As the solder 15 has cooled, the die 13 can connect with the substrate 11 by means of the solder 15.

As the die 13 is placed on the molten solder 15, the heat can flow from the molten solder 15 to the die 13; for example, the temperature of the die 13 may be about 300 degree centigrade. The heat may damage the die 13 and cause a reduction in the yield of the semiconductor device 10. In addition, the high stress may be generated in the die 13 to cause to damage the structure of the die 13.

### SUMMARY OF THE INVENTION

It is the primary objective of the present invention to provide a semiconductor device, wherein an adhesion layer that is made of aluminum can be positioned between the die and the lead frame or the substrate, such as the die can connect with the lead frame by means of the adhesion layer.

It is a secondary objective of the present invention to provide a semiconductor device, wherein a metal layer can be formed on a substrate, and a die with an adhesion layer can be poisoned on the metal layer, such as the die can connect with the substrate easily.

It is another objective of the present invention to provide a semiconductor device, wherein a back metal layer can be formed on the back surface of the die to benefit to form the adhesion layer on the die.

It is another objective of the present invention to provide a manufacturing method for the semiconductor device, wherein the adhesion layer can be formed on the die or the substrate by a plating technology or an ultrasonic bonding technology to avoid to damage the die during the manufacturing process of the adhesion layer.

It is another objective of the present invention to provide a manufacturing method for the semiconductor device, wherein the die can connect with the substrate or the lead frame with the adhesion layer by an ultrasonic bonding technology to avoid to damage the die during the manufacturing process.

In an aspect of the present invention, a semiconductor device, comprising: a lead frame; a die positioned on the lead frame; and an adhesion layer positioned between the lead frame and the die, wherein the adhesion layer comprises aluminum.

In an aspect of the present invention, a semiconductor device, comprising: a substrate; a die positioned on the substrate; and an adhesion layer positioned between the substrate and the die, wherein the adhesion layer comprises aluminum.

In an aspect of the present invention, a manufacturing method of a semiconductor device, comprising the steps of: forming an adhesion layer on a substrate or a lead frame, wherein the adhesion layer comprises aluminum; and connecting the adhesion layer with a die.

In an aspect of the present invention, a manufacturing method of a semiconductor device, comprising the steps of: forming an adhesion layer on a die, wherein the adhesion layer comprises aluminum; and connecting the adhesion layer with a lead frame or a substrate.

### BRIEF DESCRIPTION OF DRAWINGS

FIG. 1 is a diagrammatic illustration of a semiconductor device in accordance with a prior art.

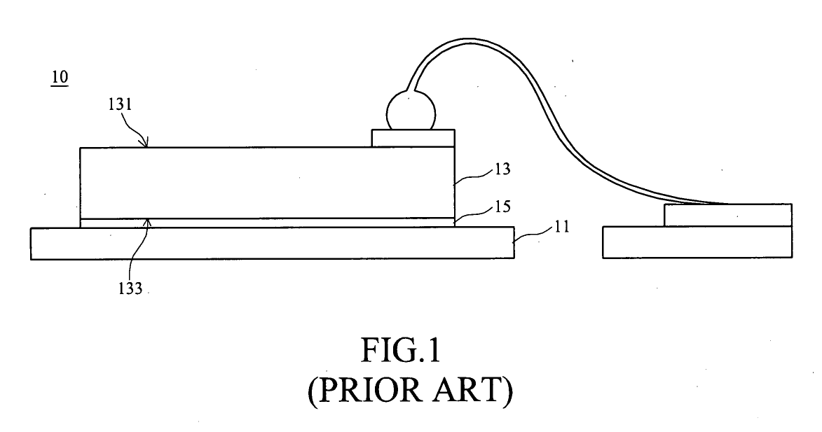

FIG. 2 is a diagrammatic illustration of a semiconductor device in accordance with an embodiment of the invention.

FIG. 3 is a diagrammatic illustration of a semiconductor device in accordance with another embodiment of the invention.

FIG. 4 is a diagrammatic illustration of a semiconductor device in accordance with another embodiment of the invention.

FIG. 5 is a diagrammatic illustration of a semiconductor device in accordance with another embodiment of the invention.

FIG. 6A and FIG. 6B are diagrammatic illustrations of manufacturing process of a semiconductor device in accordance with an embodiment of the invention.

FIG. 7A and FIG. 7B are diagrammatic illustrations of manufacturing process of a semiconductor device in accordance with an embodiment of the invention.

FIG. 8A and FIG. 8B are diagrammatic illustrations of manufacturing process of a semiconductor device in accordance with an embodiment of the invention.

FIG. 9A and FIG. 9B are diagrammatic illustrations of manufacturing process of a semiconductor device in accordance with an embodiment of the invention.

### DETAILED DESCRIPTION

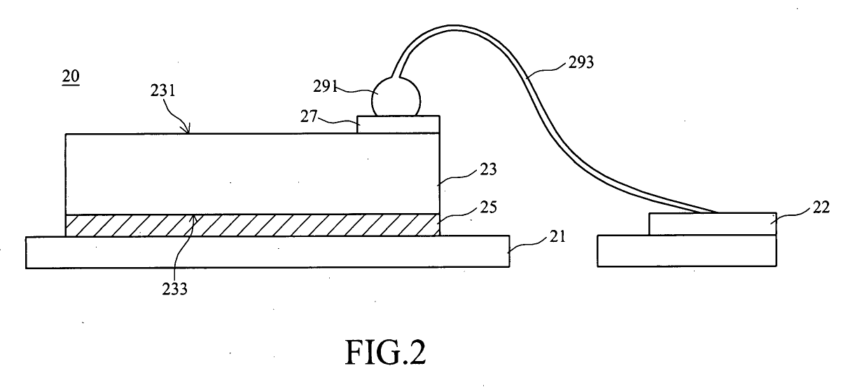

Referring to FIG. 2, there is shown a diagrammatic illustration of a semiconductor device in accordance with an embodiment of the invention. The semiconductor device 20 comprises a die 23 that connects with a substrate 21 via an adhesion layer 25, wherein the adhesion layer 25 can be made of aluminum.

The die 23 comprises an active surface 231 and a back surface 233, wherein the back surface 233 of the die 23 can connect with the substrate via the adhesion layer 25. Furthermore, there is at least one bond pad 27 positioned on the active surface 231 of the die 23, and a ball bond 291 can be positioned upon the bond pad 27 and connected with a lead 22 via a bonding wire 293.

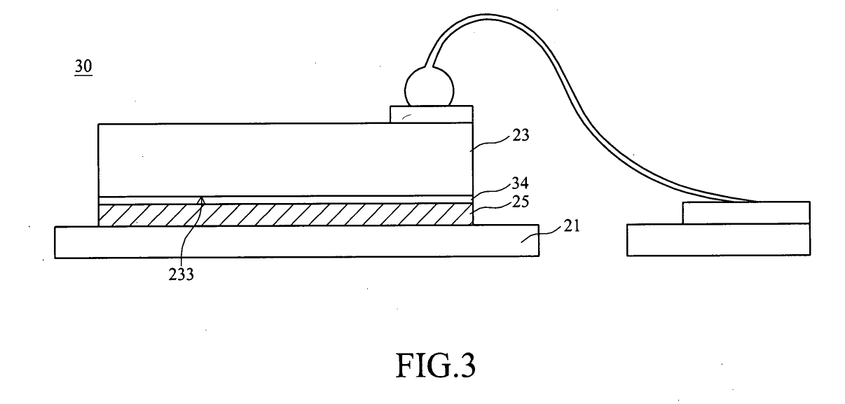

Referring to FIG. 3, there is shown a diagrammatic illustration of a semiconductor device in accordance with another embodiment of the invention. The semiconductor device 30 comprises a die 23 that connects with a substrate 21 via an adhesion layer 25, wherein the adhesion layer 25 can be made of aluminum. In addition, a back metal layer 34 is positioned between the adhesion layer 25 and the die 23.

The back metal layer 34 is formed on the back surface 233 of the die 23, and the die 23 can connect with the substrate 21 vial the back metal layer 34 and the adhesion layer 25. The adhesion layer 25 and the back metal layer 34 both are made of metal, so the die 23 with the back metal layer 34 can connect with the adhesion layer 25 more easily and stably.

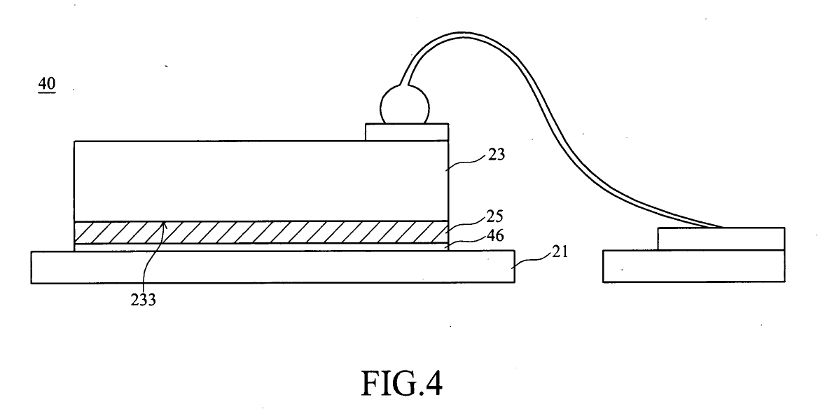

Referring to FIG. 4, there is shown a diagrammatic illustration of a semiconductor device in accordance with another embodiment of the invention. The semiconductor device 40 comprises a die 23 that connects with a substrate 21 via an adhesion layer 25, wherein the adhesion layer 25 can be made of aluminum. In addition, a metal layer 46 is positioned between the adhesion layer 25 and the substrate 21.

The metal layer 46 is formed on the top surface of the substrate 21, and the adhesion layer 25 can connect with the substrate 21 via the metal layer 46. The adhesion layer 25 and the metal layer 46 both are made of metal, such that the adhesion layer 25 can connect with the metal layer 46 more easily and stably.

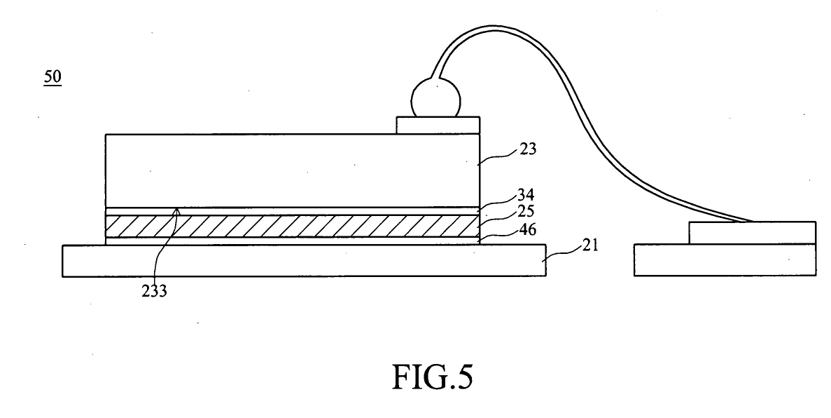

More specifically, the semiconductor device 50 comprises the back metal layer 34, the adhesion layer 25 and the metal layer 46 simultaneously. For example, the back metal layer 34 can be formed between the die 23 and the adhesion layer 25, and the metal layer 46 can be formed between the adhesion layer 25 and the substrate 21, such that the die 23 can connect with the substrate 21 by means of the back metal layer 34, the adhesion layer 25, and the metal layer 46, as shown on FIG. 5.

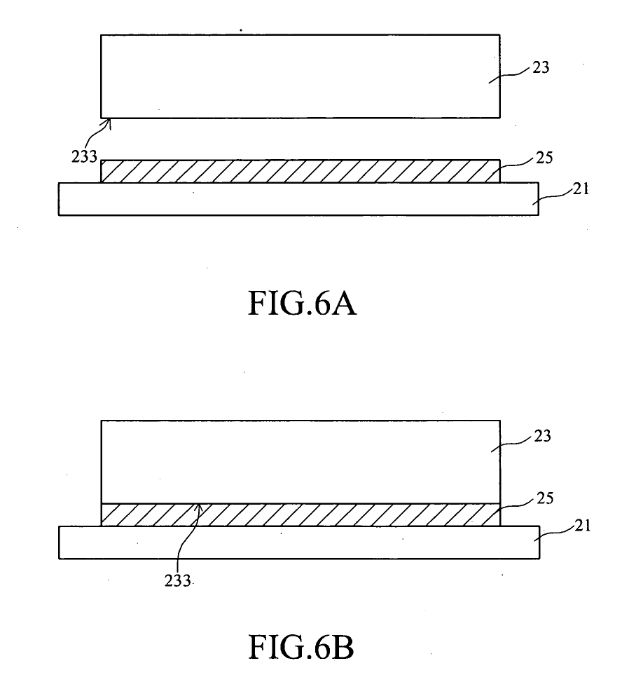

Referring to FIG. 6A and FIG. 6B, there are shown diagrammatic illustrations of manufacturing process of a semiconductor device in accordance with an embodiment of the invention. An adhesion layer 25 that is made of aluminum can be formed on the top surface of the substrate 21, wherein the adhesion layer 25 can be formed by plating technology or an ultrasonic bonding technology, as shown on FIG. 6A.

After forming the adhesion layer 25 on the substrate 21, the die 23 can be positioned on the adhesion layer 25 to connect with the substrate 21 via the adhesion layer 25 by the ultrasonic bonding technology. For example, an ultrasonic vibration can be applied on the die 23, and a pressure can be applied between the die 23 and the substrate 21, such as the die 23 can connect with the substrate 21 by means of the adhesion layer 25, as shown on FIG. 6B.

In another embodiment of the invention, the adhesion layer 25 can be formed on the back surface 233 of the die 23 firstly, and then the die 23 with the adhesion layer 25 can be positioned on the top surface of the substrate 21. Thereafter, an ultrasonic vibration can be applied on the die 23, and the substrate 21 can connect with the adhesion layer 25 of the die 23.

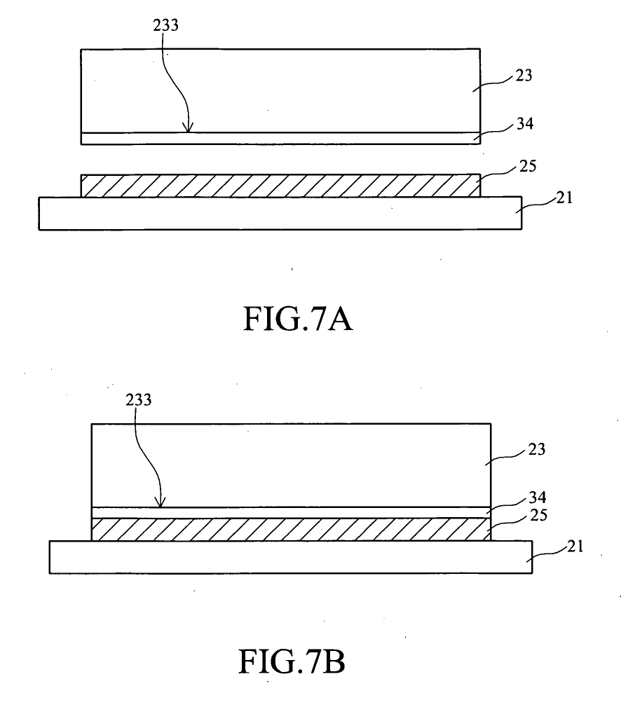

Referring to FIG. 7A and FIG. 7B, there are shown diagrammatic illustrations of manufacturing process of a semiconductor device in accordance with another embodiment of the invention. An adhesion layer 25 that is made of aluminum can be formed on the top surface of the substrate 21, and the back metal layer 34 can be formed on the back surface 233 of the die 23, wherein the back metal layer 34 and the adhesion layer 25 can be formed by a plating technology or an ultrasonic bonding technology, as shown on FIG. 7A.

The die 23 with back metal layer 34 can be positioned on the adhesion layer 25 to connect with the substrate 21 by the ultrasonic bonding technology. For example, an ultrasonic vibration can be applied on the die 23, and a pressure can be applied between the die 23 and the substrate 21, such as the die 23 can connect with the substrate 21 by means of the back metal layer 34 and the adhesion layer 25, as shown on FIG. 7B.

In another embodiment of the invention, the back metal layer 34 can be formed on the back surface 233 of the die 23, and the adhesion layer 25 can be formed on the back metal layer 34. After that, the die 23 with the back metal layer 34 and the adhesion layer 25 can be positioned on the top surface of the substrate 21, such as the die 23 can connect with the substrate 21 by the ultrasonic bonding technology.

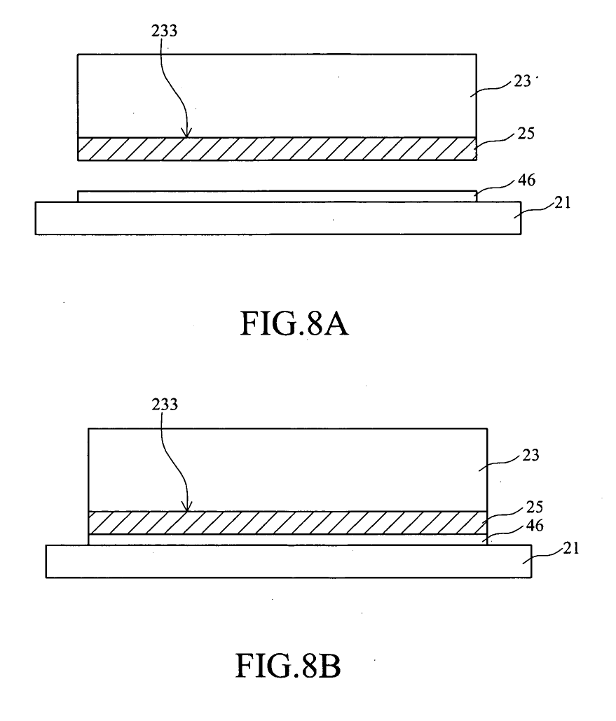

Referring to FIG. 8A and FIG. 8B, there are shown diagrammatic illustrations of manufacturing process of a semiconductor device in accordance with another embodiment of the invention. An adhesion layer 25 that is made of aluminum can be formed on the back surface 233 of the die 23, and a metal layer 46 can be formed on the top surface of the substrate 21, wherein the metal layer 46 and the adhesion layer 25 can be formed by plating technology or an ultrasonic bonding technology, as shown on FIG. 8A.

After forming the metal layer 46 on the substrate 21 and forming the adhesion layer 25 on the die 23, the die 23 with the adhesion layer 25 can be positioned on the metal layer 46 to connect with the substrate 21 by the ultrasonic bonding technology. For example, an ultrasonic vibration can be applied on the die 23, and a pressure can be applied between the die 23 and the substrate 21, such as the die 23 can connect with the substrate 21 by means of the adhesion layer 25 and the metal layer 46, as shown on FIG. 8B.

In another embodiment of the invention, the metal layer 46 and the adhesion layer 25 can be formed on the substrate 21 in turn, and the die 23 can be positioned on the adhesion layer 25, such as the die 23 can connect with the substrate 21 via the adhesion layer 25 and the metal layer 46.

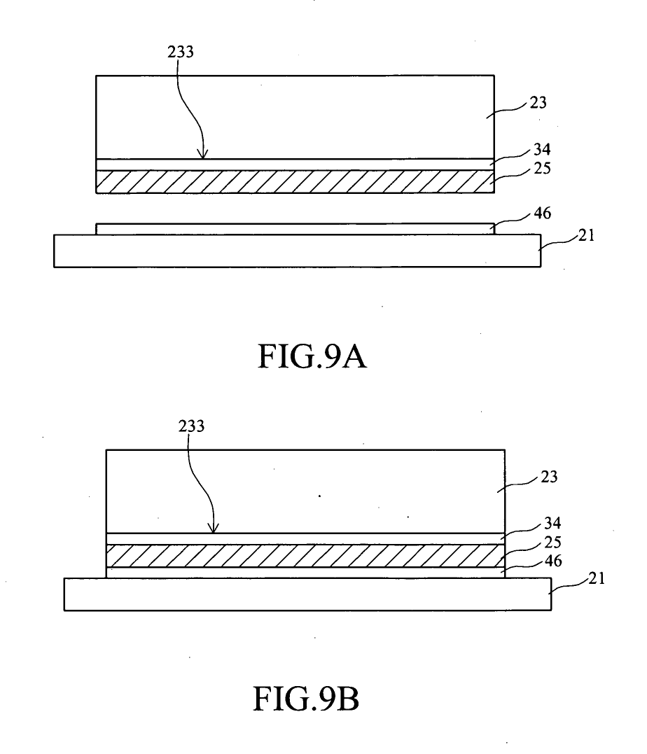

Preferably, the back metal layer 34, the adhesion layer 25, and the metal layer 46 can be formed between the die 23 and the substrate 21. For example, the back metal layer 34 can be formed on the back surface 233 of the die 23, the metal layer 46 can be formed on the top surface of the substrate 21, and the adhesion layer 25 can be formed on the back metal layer 34 or on the metal layer 46, such as the die 23 with the back metal layer 34 can connect with the substrate 21 with the metal layer 46 via the adhesion layer 25 by the ultrasonic bonding technology, as shown of FIG. 9A and FIG. 9B.

In above embodiment of the invention, the die 23 is connected with the substrate 21. Moreover, the substrate 21 also can be a lead frame 21, such as the die 23 can be connected with the lead frame 21 via the adhesion layer 25, the back metal layer 34 and/or the metal layer 46. The lead frame 21 can be made of metal, such that the die 25 can connect with the lead frame 21 without the metal layer 34.

The present invention is not limited to the above-described embodiments. Various alternatives, modifications, and equivalents may be used. Therefore, the above embodiments should not be taken as limiting the scope of the invention, which is defined by the appending claims.

1. A semiconductor device, comprising:
a lead frame;
a die positioned on said lead frame; and
an adhesion layer positioned between said lead frame and said die, wherein said adhesion layer comprises aluminum.

2. The semiconductor device of claim 1, comprising a metal layer positioned between said lead frame and said adhesion layer.

3. The semiconductor device of claim 2, comprising a back metal layer positioned between said die and said adhesion layer.

4. The semiconductor device of claim 1, comprising a back metal layer positioned between said die and said adhesion layer.

5. The semiconductor device of claim 1, wherein said die comprises an active surface and a back surface, and a bond pad and a ball bond are positioned on said active surface in turn.

6. The semiconductor device of claim 5, comprising a bonding wire connected with said ball bond.

7. A semiconductor device, comprising:
a substrate;
a die positioned on said substrate; and
an adhesion layer positioned between said substrate and said die, wherein said adhesion layer comprises aluminum.

8. The semiconductor device of claim 7, comprising a metal layer positioned between said substrate and said adhesion layer.

9. The semiconductor device of claim 8, comprising a back metal layer positioned between said die and said adhesion layer.

10. The semiconductor device of claim 7, comprising a back metal layer positioned between said die and said adhesion layer.

11. A manufacturing method of a semiconductor device, comprising the steps of:
forming an adhesion layer on a substrate or a lead frame, wherein said adhesion layer comprises aluminum; and
connecting said adhesion layer with a die.

12. The manufacturing method of claim 11, wherein said adhesion layer is formed by a plating technology or an ultrasonic bonding technology.

13. The manufacturing method of claim 11, wherein said die is connected with said adhesion layer by an ultrasonic bonding technology.

14. The manufacturing method of claim 11, comprising the steps of:
forming a metal layer between said adhesion layer and said lead frame or said substrate.

15. The manufacturing method of claim 11, comprising the steps of:
forming a back metal layer between said adhesion layer and said die.

16. A manufacturing method of a semiconductor device, comprising the steps of:
forming an adhesion layer on a die, wherein said adhesion layer comprises aluminum; and
connecting said adhesion layer with a lead frame or a substrate.

17. The manufacturing method of claim 16, wherein said adhesion layer is formed by a plating technology or an ultrasonic bonding technology.

18. The manufacturing method of claim 16, wherein said adhesion layer is connected with said lead frame or said substrate by an ultrasonic bonding technology.

19. The manufacturing method of claim 16, comprising the steps of:
forming a metal layer between said adhesion layer and said lead frame or said substrate.

20. The manufacturing method of claim 16, comprising the steps of:
forming a back metal layer between said adhesion layer and said die.
